(19) United States
(12) Patent Application Publication
(10) Pub. No.: US 2026/0123324 A1
(43) Pub. Date: Apr. 30, 2026

(54) SUBSTRATE PROCESSING METHOD AND APPARATUS

(71) Applicant: SEMES CO., LTD., Cheonan-si (KR)

(72) Inventors: Hee Jae GOO, Cheonan-si (KR); Jae Ho YOO, Seoul (KR)

(73) Assignee: SEMES CO., LTD., Cheonan-si (KR)

(21) Appl. No.: 19/372,446

(22) Filed: Oct. 29, 2025

(30) Foreign Application Priority Data
Oct. 29, 2024 (KR) 10-2024-0149379

(51) Int. Cl. H01L 21/67

(52) U.S. Cl. CPC H10P 72/0404

(57) ABSTRACT

Disclosed is a method of processing a substrate, the method including: processing a substrate by supplying a treatment liquid to the substrate through a liquid supply line in which an opening/closing valve and a suck-back valve are installed; closing the opening/closing valve based on a first opening/closing profile; and performing a suck-back operation based on a first suck-back profile, in which the first opening/closing profile includes information on a closing slope, which is a slope of a pneumatic pressure applied to the opening/closing valve over time, the first suck-back profile includes information on a suck-back slope, which is a slope of a pneumatic pressure applied to the suck-back valve over time, and the first suck-back profile includes a plurality of different suck-back slopes.

### CROSS-REFERENCE TO RELATED APPLICATION

This application claims priority to and the benefit of Korean Patent Application No. 10-2024-0149379 filed in the Korean Intellectual Property Office on Oct. 29, 2024, the entire contents of which are incorporated herein by reference.

### TECHNICAL FIELD

The present invention relates to a substrate processing method and apparatus for processing a substrate with a treatment liquid.

### BACKGROUND ART

In order to manufacture a semiconductor device or a liquid crystal display, various processes, such as photolithography, ashing, etching, ion implantation, thin film deposition, and cleaning, of a substrate may be performed. Among them, the cleaning process is a process for removing particles remaining on the substrate, and is performed before and after each process.

Among them, the photolithography process is a process of forming a desired pattern on a wafer. The photolithography process is usually carried out in a spinner local facility to which an exposure facility is connected to continuously process an applying process, an exposure process, and a developing process. These spinner facility sequentially or selectively performs a Hexamethyl Disilazane (HMDS) treatment process, an applying process, a baking process, and a developing process.

Meanwhile, during the process of manufacturing the substrate, a substrate processing process is performed by supplying a liquid to the substrate. Liquid supply to the substrate is performed through a nozzle through a liquid supply line. After that, a cutoff operation is performed by closing a flow path through an opening/closing valve installed in the liquid supply line. The suck-back is performed to suck-back the liquid remaining in the nozzle again through the suck-back valve in in order to prevent the liquid remaining in the nozzle from being supplied to the substrate after performing the cutoff operation, and the control of the opening/closing valve and the suck-back valve is performed through a speed controller. Here, the cutoff state and the suck-back state change depending on the opening/closing speed of the opening/closing valve, the shape of the nozzle, and the flow rate of the liquid, and the like, but when the opening/closing valve and the suck-back valve are controlled through a speed controller, there is a problem in that only the opening/closing speed and the internal volume of the opening/closing valve and the suck-back valve may be controlled.

### SUMMARY OF THE INVENTION

The present invention has been made in an effort to provide a substrate processing method and apparatus capable of efficiently processing a substrate.

The present invention has also been made in an effort to provide a substrate processing method and apparatus capable of controlling an opening/closing valve in real time by determining a cutoff state of a nozzle in real time.

The present invention has also been made in an effort to provide a substrate processing method and apparatus capable of controlling a suck-back valve in real time by determining a suck-back state of a nozzle in real time.

The present invention has also been made in an effort to provide a substrate processing method and apparatus capable of controlling an opening/closing valve and a suck-back valve using a single pressure control device.

The objectives of the present disclosure are not limited thereto and other objectives not stated herein may be clearly understood by those skilled in the art from the following description.

An exemplary embodiment of the present disclosure, a method of processing a substrate, the method comprising: processing a substrate by supplying a treatment liquid to the substrate through a liquid supply line in which an opening/closing valve and a suck-back valve are installed; closing the opening/closing valve based on a first opening/closing profile; and performing a suck-back operation based on a first suck-back profile, wherein the first opening/closing profile includes information on a closing slope, which is a slope of a pneumatic pressure applied to the opening/closing valve over time, the first suck-back profile includes information on a suck-back slope, which is a slope of a pneumatic pressure applied to the suck-back valve over time, and the first suck-back profile may includes a plurality of different suck-back slopes.

An exemplary embodiment of the present disclosure, an apparatus for processing a substrate, the apparatus comprising: a housing having a treatment space therein; a support unit for supporting a substrate in the treatment space; a liquid supply unit for supplying a treatment liquid to the substrate; and a controller for controlling the liquid supply unit, wherein the liquid supply unit includes: a liquid supply line through which the treatment liquid flows; a nozzle connected to the liquid supply line to supply the treatment liquid to the substrate; an opening/closing valve provided on the liquid supply line; a suck-back valve provided adjacent to the opening/closing valve; and a pressure control device for controlling at least one of the opening/closing valve and the suck-back valve, and the controller instructs the pressure control device to close the opening/closing valve based on the first opening/closing profile and control the opening/closing valve and the suck-back valve to perform a suck-back operation based on the first suck-back profile, the first opening/closing profile includes information on a closing slope, which is a slope of a pneumatic pressure applied to the opening/closing valve over time, the first suck-back profile includes information on a suck-back slope, which is a slope of the pneumatic pressure applied to the suck-back valve over time, and the first suck-back profile may includes a plurality of different suck-back slopes.

An exemplary embodiment of the present disclosure, a method of processing a substrate, the method comprising: processing a substrate by supplying a treatment liquid to the substrate through a liquid supply line in which an opening/closing valve and a suck-back valve are installed; closing the opening/closing valve based on a first opening/closing profile; and performing a suck-back operation based on a first suck-back profile, the first opening/closing profile includes information on a closing slope, which is a slope of a pneumatic pressure applied to the opening/closing valve over time, the first suck-back profile includes information on a suck-back slope, which is a slope of the pneumatic pressure applied to the suck-back valve over time, and the suck-back slope is plural, the performing of the suck-back operation based on the first suck-back profile includes: adjusting a pressure of the suck-back valve from a first suck-back pressure to a second suck-back pressure by controlling the pneumatic pressure applied to the suck-back valve based on a first suck-back slope among the plurality of suck-back slopes; djusting a pressure of the suck-back valve from the second suck-back pressure to a third suck-back pressure by controlling the pneumatic pressure applied to the suck-back valve based on a second suck-back slope among the plurality of suck-back slopes; and the second suck-back pressure and the third suck-back pressure are the same pressure.

According to the exemplary embodiment of the present invention, it is possible to efficiently process a substrate.

According to the exemplary embodiment of the present invention, it is possible to obtain a cutoff state of a nozzle in real time through a photographing device, and control pneumatic pressure applied to an opening/closing valve in real time based on the cutoff state.

According to the exemplary embodiment of the present invention, it is possible to obtain a suck-back state of a nozzle in real time through a photographing device, and control pneumatic pressure applied to a suck-back valve in real time based on the suck-back state.

According to the exemplary embodiment of the present invention, it is possible to control an opening/closing valve and a suck-back valve using a single pressure control device.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a front view of the substrate processing apparatus of FIG. 1.

FIG. 3 is a top plan view of an applying block in the substrate processing apparatus of FIG. 1.

FIG. 4 is a top plan view of a developing block in the substrate processing apparatus of FIG. 1.

FIG. 5 is a top plan view schematically illustrating a transfer robot of FIG. 3.

FIG. 6 is a top plan view schematically illustrating an example of a heat treating chamber of FIG. 3 or FIG. 4.

FIG. 7 is a front view of a heat treating chamber of FIG. 6.

FIG. 8 is a cross-sectional view schematically illustrating an example of a liquid treating chamber of FIG. 3 or FIG. 4.

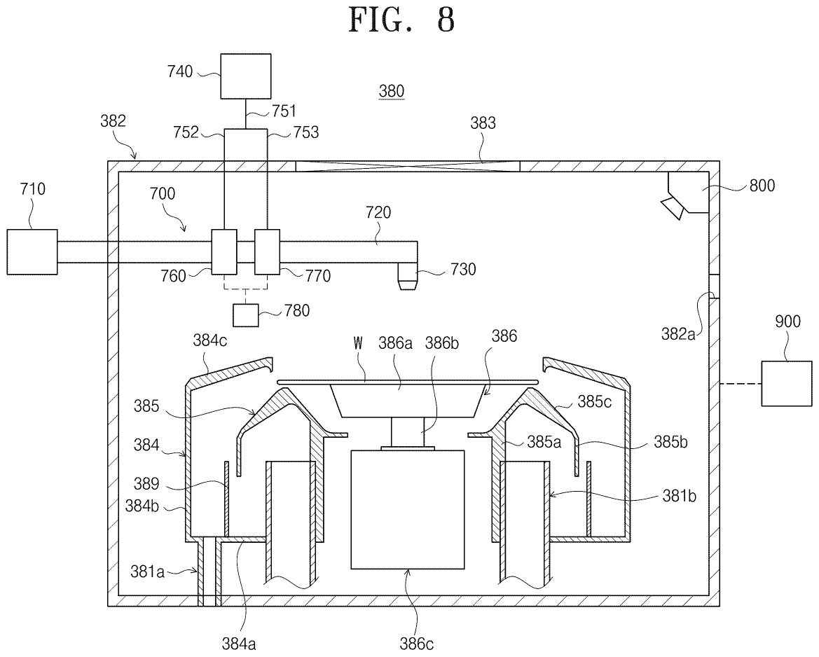

FIG. 9 is a diagram illustrating a liquid supply unit according to an exemplary embodiment of the present invention.

FIG. 10 is a flowchart illustrating a substrate processing method according to an exemplary embodiment of the present invention.

FIG. 11 is a conceptual view for describing an opening/closing operation according to an exemplary embodiment of the present invention.

FIG. 12 is a conceptual view for describing a suck-back operation according to an exemplary embodiment of the present invention.

FIGS. 13 to 15 are diagrams for describing a cutoff state according to the exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to apparatuses used for treating other types of substrates, other than wafers, as targets to be treated.

Hereinafter, an exemplary embodiment of the present invention will be described with reference to the accompanying drawings.

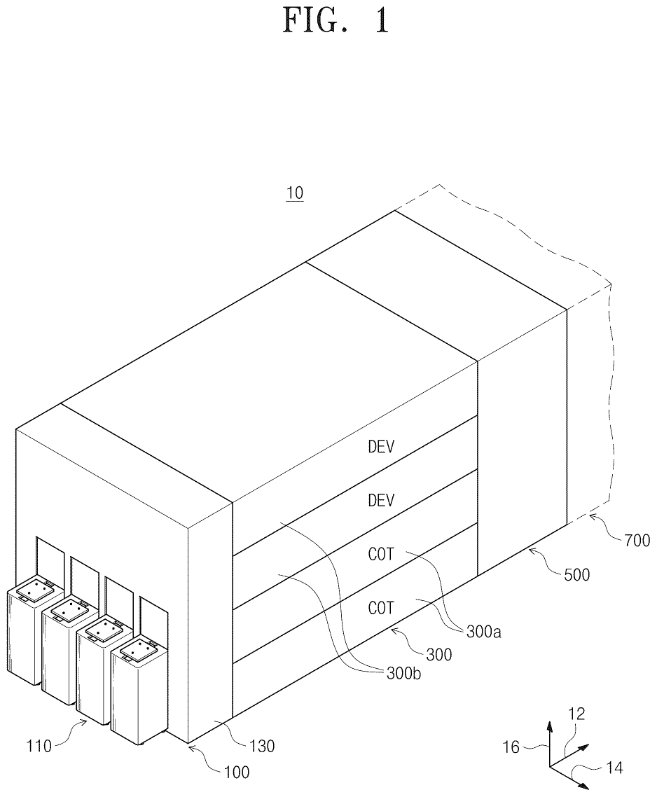

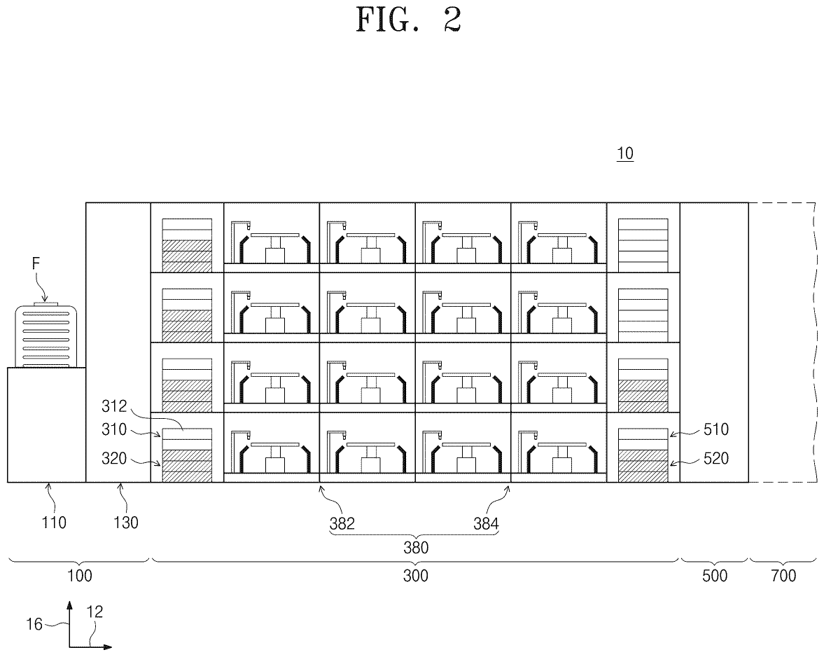

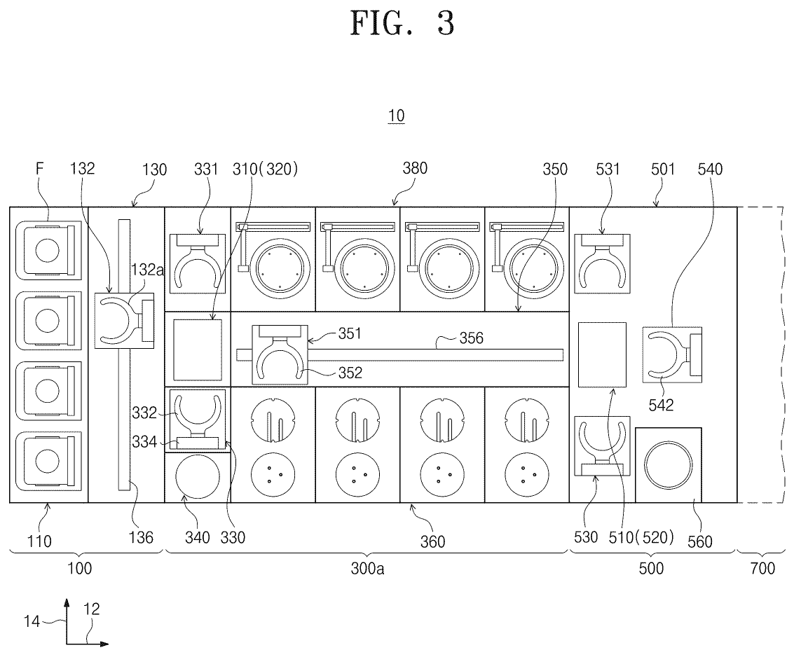

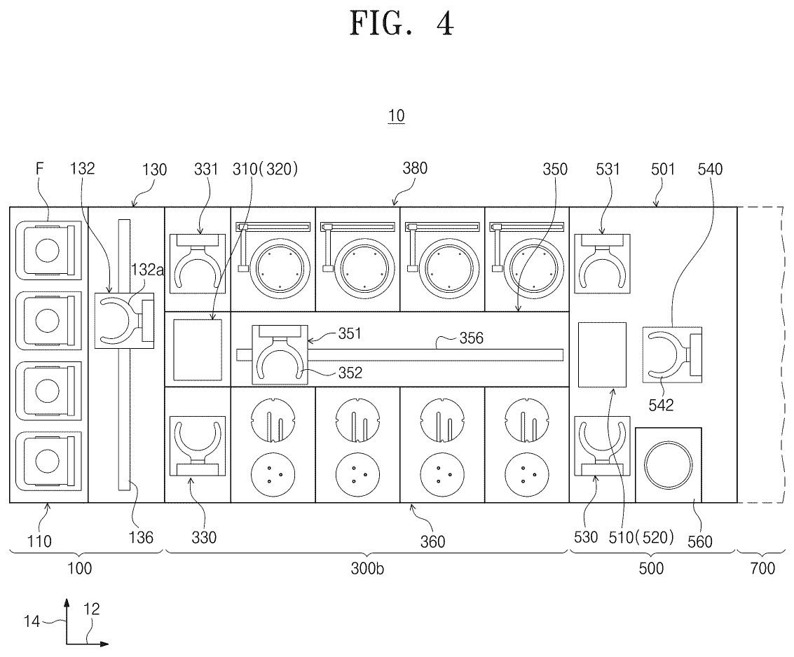

FIG. 1 is a top plan view schematically illustrating a substrate processing apparatus according to an exemplary embodiment of the present invention, and FIG. 2 is a front view of the substrate processing apparatus of FIG. 1. FIG. 3 is a top plan view of an applying block in the substrate processing apparatus of FIG. 1, and FIG. 4 is a top plan view of a developing block in the substrate processing apparatus of FIG. 1.

Referring to FIGS. 1 to 4, a substrate processing apparatus 10 includes an index module 100, a treating module 300, and an interface module 500. According to the exemplary embodiment, the index module 100, the treating module 300, and the interface module 500 are sequentially arranged in a line. Hereinafter, a direction in which the index module 100, the treating module 300, and the interface module 500 are disposed is referred to as a first direction 12, and when viewed from above, a direction perpendicular to the first direction 12 is referred to as a second direction 14, and a direction perpendicular to both the first direction 12 and the second direction 14 is referred to as a third direction 16.

The index module 100 is provided to transfer the substrate W between a container F in which the substrate W is accommodated and the treating module 300. A longitudinal direction of the index module 100 is provided in the second direction 14. The index module 100 includes a load port 110 and an index frame 130. The containers F in which the substrates W are accommodated are placed on the load ports 110. Based on the index frame 130, the load port 110 is located at a side opposite to the treating module 300. A plurality of load ports 110 may be provided, and the plurality of load ports 110 may be disposed in the second direction 14.

For example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided to the index frame 130. A guide rail 136 is provided to the inside of the index frame 130. A longitudinal direction of the guide rail 136 is provided in the second direction 14. The index robot 132 is mounted on the guide rail 136 to be movable along the guide rail 136. The index robot 132 includes a hand 132a on which the substrate W is placed. The hand 132a may be provided to be capable of forward and backward movement, linear movement in the third direction, and rotational movement in the third direction 16.

The treating module 300 may perform an application process and a development process on the substrate W. The treating module 300 includes an applying block 300a and a developing block 300b.

The applying block 300a performs an application process on the substrate W before the exposure process is performed. The developing block 300b performs a development process on the substrate W after the exposure process is performed. A plurality of applying blocks 300a is provided. A plurality of applying blocks 300a may be provided to be stacked on each other. A plurality of developing blocks 300b may be provided. A plurality of developing blocks 300b may be provided to be stacked on each other. According to an example, two applying blocks 300a are provided, and two developing blocks 300b are provided. A plurality of applying blocks 300a may be positioned under the developing block 300b.

According to an example, the plurality of applying blocks 300a may be provided in the same structure. The films applied to the substrate W in each of the plurality of applying blocks 300a may be the same type of film. Optionally, depending on the applying block 300a, the films applied to the substrate W may be different types of films. The film applied to the substrate W includes a photoresist film. The film applied to the substrate W may further include an antireflection film. Optionally, the film applied to the substrate W may further include a protective film.

Furthermore, the two developing blocks 300b may be provided in the same structure. The developer supplied to the substrate W by the plurality of developing blocks 300b may be the same type of liquid. Optionally, the developer supplied to the substrate W according to the developing block 300b may be different types of developer. For example, when performing the process of removing the light-irradiated area of the register film on the substrate W, the developing process may be performed on one of the two developing blocks 300b, and when performing the process of removing the area not irradiated with light, the developing process may be performed on the other of the two developing blocks 300b.

Referring back to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index module 100. The hydrophobization chamber 340 and the buffer unit 310 may be sequentially disposed along the second direction 14. Also, the cooling unit 320 and the buffer unit 310 may be stacked in a vertical direction.

The buffer unit 310 includes one or a plurality of buffers 312. When a plurality of buffers 312 is provided, a plurality of buffers 312 may be disposed to be stacked therebetween. The buffer 312 provides a space in which the substrate W stays when the substrate W is transferred between the index module 100 and the treating module 300. The hydrophobization chamber 340 hydrophobizes the surface of the substrate W. The hydrophobization treatment may be performed before performing the application process on the substrate W. The hydrophobization treatment may be performed by supplying the hydrophobization gas to the substrate W while heating the substrate W. The cooling unit 320 cools the substrate W. The cooling unit 320 includes one or a plurality of cooling plates. When a plurality of cooling plates is provided, a plurality of cooling plates may be disposed to be stacked on each other. According to an example, the cooling unit 320 may be disposed below the buffer unit 310. A flow path through which cooling water flows may be formed in the cooling plate. The substrate W on which the hydrophobization treatment has been completed may be cooled in the cooling plate.

A transfer mechanism 330 is provided between the hydrophobization chamber 340 and the buffer unit 310 and between the hydrophobization chamber 340 and the cooling unit 320. The transfer mechanism 330 is provided to be able to transfer the substrate W between the buffer unit 310, the hydrophobization chamber 340, and the cooling unit 320.

The transfer mechanism 330 includes a hand 322 on which the substrate W is placed, and the hand 332 may be provided to be movable forward and backward, rotatable about the third direction 16, and movable along the third direction 16. According to an example, the transfer mechanism 330 is moved in the third direction 16 along the guide rail 334. The guide rail 334 extends from the applying block located at the bottommost end among the applying blocks 300a to the developing block located at the topmost end among the developing blocks 300b. Accordingly, the transfer mechanism 330 may transfer the substrate W between the blocks 300a and 300b provided on different layers. For example, the transfer mechanism 330 may transfer the substrate W between the applying blocks 300a positioned on different layers. In addition, the transfer mechanism 330 may transfer the substrate W between the applying block 300a and the developing block 300b.

Furthermore, another transfer unit 331 may be additionally provided at an opposite side to the side to which the hydrophobization chamber 340 is provided with respect to the buffer unit 310. Furthermore, the other transfer unit 331 may be provided to transfer the substrate W between the buffer unit 310 and the cooling unit 320 provided in different blocks 300a and 300b. Furthermore, the other transfer unit 331 may be provided to transfer the substrate W between the buffer unit 310 and the cooling unit 320 provided in different blocks 300a and 300b.

The transfer chamber 350 may be provided so that a longitudinal direction is parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treating chambers 360 is provided. Some of the heat treating chambers 360 are disposed along the first direction 12. Optionally, some of the liquid treating chambers 360 may be stacked along the third direction 16. All of the heat treating chambers 360 may be located on one side of the transfer chamber 350.

The liquid treating chamber 380 performs a liquid film forming process of forming a liquid film on the substrate W. According to an example, the liquid film forming process includes a resist film forming process. The liquid film forming process may include an antireflection film forming process. Optionally, the liquid film forming process may further include a protective film forming process. A plurality of liquid treating chambers 380 is provided. The liquid treating chambers 380 may be located on the side opposite to the heat treating chamber 360. For example, all liquid treating chambers 380 may be located on the other side of the transfer chamber 350. The liquid treating chambers 380 are arranged side by side along the first direction 12. Optionally, some of the liquid treating chambers 360 may be stacked along the third direction 16.

According to an example, the liquid treating chambers 380 include a front end liquid treating chamber 382a and a rear end liquid treating chamber 380b. The front end liquid treating chamber 380a is disposed relatively adjacent to the index module 100, and the rear end liquid treating chamber 380b is disposed more adjacent to the interface module 500.

The front liquid treating chamber 380 applies a first liquid on the substrate W, and the rear liquid treating chamber 364 applies a second liquid on the substrate W. The first liquid and the second liquid may be different types of liquids. According to an example, the first liquid may be a liquid for forming the antireflection film, and the second liquid may be a liquid for forming the photoresist film. The photoresist film may be formed on the substrate W to which the antireflection film is applied. Optionally, the first liquid may be a liquid for forming the photoresist film, and the second liquid may be a liquid for forming the antireflection film. In this case, the antireflection film may be formed on the substrate W on which the photoresist film is formed. Optionally, the first liquid and the second liquid may be the same type of liquid, and all of these may be liquids for forming a photoresist film.

Referring back to FIG. 4, the developing block 300b includes a buffer unit 310, a cooling unit 320, a transfer chamber 350, and a liquid treating chamber 380. The disposition of the buffer unit 310, the cooling unit 320, the transfer chamber 350, the heat treating chamber 360, and the liquid treating chamber 380 in the developing block 300b may be the same as the disposition of the buffer unit 310, the cooling unit 320, the transfer chamber 350, the heat treating chamber 360, and the liquid treating chamber 380 in the applying block 300a. When viewed from above, the buffer unit 310, the cooling unit 320, the transfer chamber 350, the heat treating chamber 360, and the liquid treating chamber 380 in the developing block 300b may be disposed at positions overlapping the positions of the buffer unit 310, the cooling unit 320, the transfer chamber 350, the heat treating chamber 360, and the liquid treating chamber 380 in the applying block 300a.

The heat treating chamber 360 performs a heating process on the substrate W. The heating process includes a post-exposure baking process performed on the substrate W on which the exposure process has been completed and a hard baking process performed on the substrate W on which the development process has been completed.

The liquid treating chamber performs a developing process of supplying a developer onto the substrate W and developing the substrate W.

In FIG. 3 or 4, a transfer robot 351 is provided in the transfer chamber 350. The transfer robot 351 transfers the substrate W between the buffer unit 310, the cooling unit 320, the heat treating chamber 360, the liquid treating chamber 380, and the buffer unit 510 or the cooling unit 520 of the interface module 500. According to an example, the transfer robot 351 has a hand 352 on which the substrate W is placed. The hand 352 may be provided to move forward and backward, rotate around the third direction 16, and be movable along the third direction 16. A guide rail 356 whose longitudinal direction is provided parallel to the first direction 12 is provided in the transfer chamber 350, and the transfer robot 351 may be provided movable on the guide rail 356.

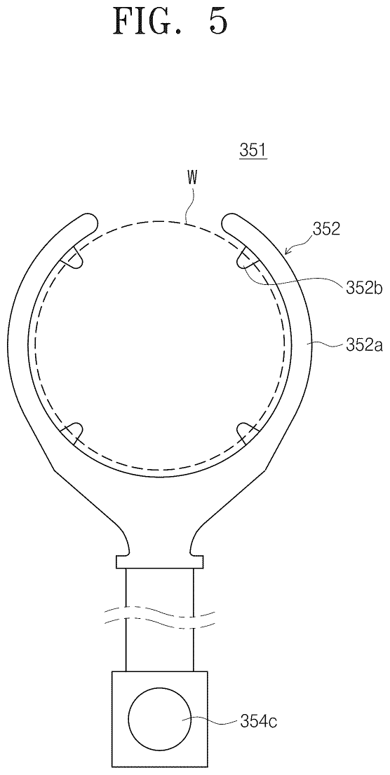

FIG. 5 is a diagram illustrating an example of the hand of the transfer robot. Referring to FIG. 5, the hand 352 includes a base 352a and a support protrusion 352b. The base 352a may have an annular ring shape in which a portion of the circumference is bent. The base 352a has an inner diameter larger than the diameter of the substrate W. The support protrusion 352b extends inward from the base 352a. A plurality of support protrusions 354b is provided and supports an edge region of the substrate W. According to an example, four support protrusions 354b may be provided at equal intervals.

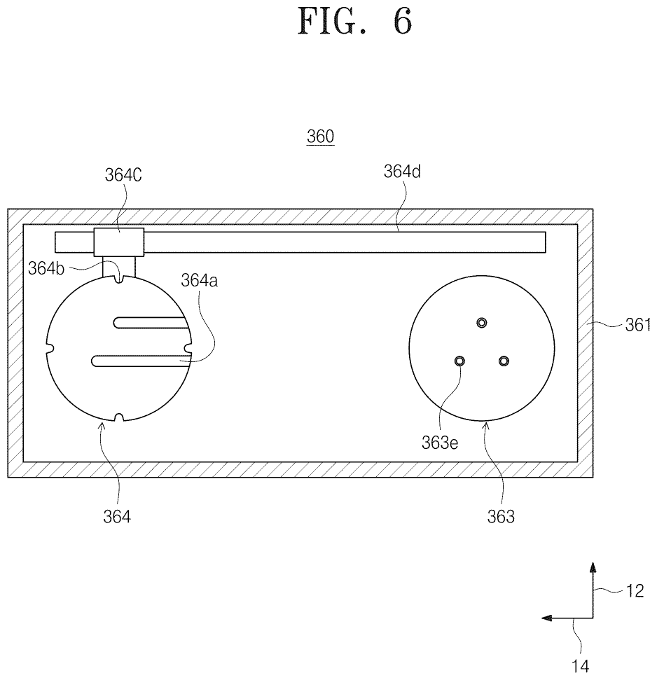

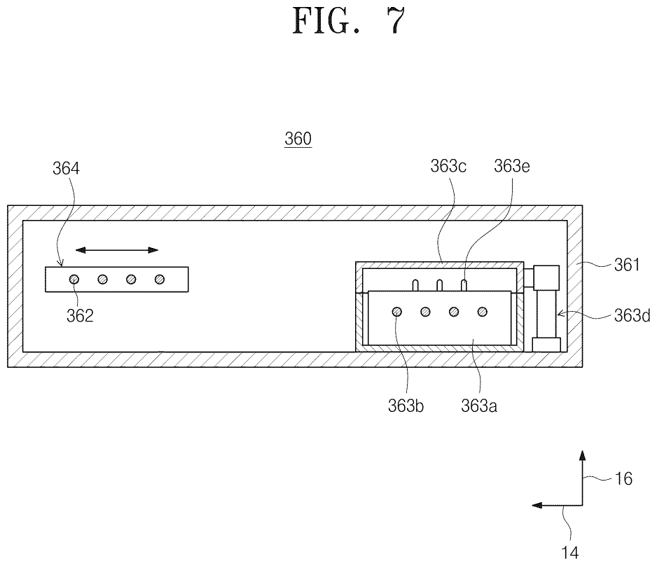

FIG. 6 is a top plan view schematically illustrating one example of the heat treating chamber of FIG. 3 or FIG. 4, and FIG. 7 is a front view of the heat treating chamber of FIG. 6.

Referring to FIGS. 6 and 7, the heat treating chamber 360 includes a housing 361, a heating unit 363, and a transfer plate 364.

The housing 361 is provided in a generally rectangular parallelepiped shape. An entrance opening (not illustrated) through which the substrate W enters and exits is formed on a sidewall of the housing 361. The entrance opening may remain open. Optionally, a door (not illustrated) may be provided to open and close the entrance opening. The heating unit 363 and the transfer plate 364 are provided within the housing 361.

The heating unit 363 includes a heating plate 363a, a cover 363c, and a heater 363b. When viewed from above, the heating plate 363a has a generally circular shape. The heating plate 363a has a larger diameter than the substrate W. The heater 363b is installed on the heating plate 363a. The heater 363b may be provided as a heating wire or a heating pattern that generates heat by supplying power. A lift pin 363e is provided at the heating plate 363a. The lift pin 363e is provided to be movable in the vertical direction along the third direction 16. The lift pin 363e receives the substrate W from the transfer robot 351 and puts the substrate W down on the heating plate 363a or lifts the substrate W up from the heating plate 363a to hand over the substrate to the transfer robot 351. According to an example, three lift pins 363e may be provided. The cover 363c has an inner space with an open lower portion. The cover 363c is positioned above the heating plate 363a and is moved in the vertical direction by a driver 363d. A space formed by the cover 363c and the heating plate 363a by moving the cover 363c is provided as a heating space for heating the substrate W.

The transfer plate 364 is generally provided with a disk shape and has a diameter corresponding to that of the substrate W. A notch 364b is formed at an edge of the transfer plate 364. The notch 364b may have a shape corresponding to that of the protrusion 352b formed in the hand of the transfer robot 351 described above. Also, the notches 364b are provided by the number corresponding to that of the protrusions 352b formed in the hand, and are formed at positions corresponding to the protrusions 352b. When the upper and lower positions of the hand and the transfer plate 364 are changed at the position where the hand and the transfer plate 364 are aligned in the vertical direction, the substrate W is transferred between the hand 354 and the transfer plate 364. The transfer plate 364 is mounted on the guide rail 364d and may be moved along the guide rail 364d by the driver 364c.

A plurality of slit-shaped guide grooves 364a is provided in the transfer plate 364. The guide groove 364a extends from the distal end of the transfer plate 364 to the inside of the transfer plate 364. The guide groove 364a is provided so that a longitudinal direction thereof is the second direction 14, and the guide grooves 364a are spaced apart from each other along the first direction 12. The guide groove 364a prevents the transfer plate 364 and the lift pin 363e from interfering with each other when the substrate W is taken over between the transfer plate 364 and the heating unit 363.

The transfer plate 364 is made of a material having high thermal conductivity. According to an example, the transfer plate 364 may be made of a metal material.

A cooling flow path 364 is formed in the transfer plate 364. Cooling water is supplied to the cooling flow path. The substrate W on which the heating has been completed in the heating unit 363 may be cooled in the middle of being transferred by the transfer plate 364. In addition, while the transfer plate 364 is stopped for the hand-over of the substrate W by the transfer robot 351, the substrate W may be cooled on the transfer plate 364.

Optionally, a cooling unit may be additionally provided in the housing 361. In this case, the cooling unit may be disposed side by side the heating unit 363. The cooling unit may be provided as a cooling plate having a passage through which cooling water flows. The substrate on which heating in the heating unit has been completed may be transferred to the cooling unit to be cooled.

FIG. 7 is a cross-sectional view schematically illustrating an example of the liquid treating chamber of FIG. 3 or FIG. 4.

Referring to FIG. 7, the liquid treating chamber 380 includes a housing 382, a treatment container 384, a support unit 386, and a liquid supply unit 700.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

An outer cup 384 is provided in the inner space of the housing 382. The outer cup 384 has a treatment space with an open top.

The support unit 386 supports the substrate W in the treatment space of the outer cup 384. The support unit 386 includes a support plate 386a, a rotary shaft 386b, and a driver 386c. The support plate 386a has a circular upper surface. The support plate 386a has a smaller diameter than the substrate W. The support plate 386a is provided to support the substrate W by vacuum pressure. The rotary shaft 386b is coupled to the center of the bottom surface of the support plate 386a, and the rotary shaft 386b is provided with the driver 386c that provides the rotary shaft 386b with rotating force. The driver 386c may be a motor. Also, a lifting driver (not illustrated) for adjusting a relative height of the support plate 386a and the outer cup 384 may be provided.

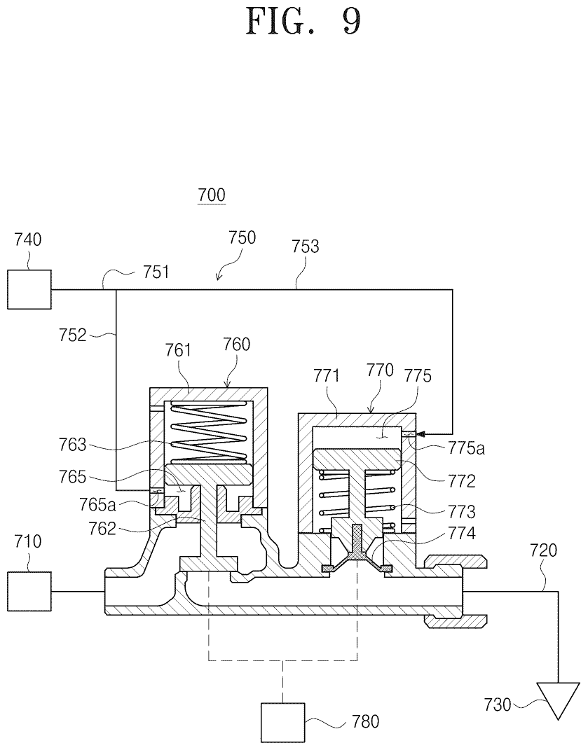

FIG. 9 is a diagram illustrating the liquid supply unit according to an exemplary embodiment of the present invention.

Referring to FIG. 9, the liquid supply unit 700 may include a liquid supply source 710, a liquid supply line 720, a nozzle 730, a gas supply source 740, a gas supply line 750, an opening/closing valve 760, a suck-back valve 770, and a pressure control device 780.

A treatment liquid is stored in the liquid supply source 710. For example, when the liquid treating chamber 380 is provided to the applying block 300a, the treatment liquid may be a liquid for forming a photoresist film, an antireflection film, or a protective film. When the liquid treating chamber 380 is provided to the developing block 300b, the treatment liquid may be a developer. The liquid supply source 710 is connected to the liquid supply line 720. The liquid supply source 710 may supply the treatment liquid to the liquid supply line 720.

The liquid supply line 720 may receive the treatment liquid from the liquid supply source 710. The treatment liquid may flow through the liquid supply line 720. The liquid supply line 720 is connected to the nozzle 730. The treatment liquid supplied to the liquid supply line 720 may flow to the nozzle 730.

The nozzle 730 is connected to the liquid supply line 720. The treatment liquid may flow through the nozzle 730 from the liquid supply line 720. The nozzle 730 may discharge the treatment liquid to the substrate W.

Gas is stored in the gas supply source 740. The gas supply source 740 is connected to the gas supply line 750. The gas supply source 740 may supply gas to the gas supply line 750.

The gas supply line 750 may include a first supply line 751, a second supply line 752, and a third supply line 753.

The first supply line 751 is connected to the gas supply source 740. The first supply line 751 may receive gas from the gas supply source 740.

The second supply line 752 and the third supply line 753 are branched from the downstream of the first supply line 751. The gas supplied to the first supply line 751 may flow through the second supply line 752 and the third supply line 753. The second supply line 752 and the third supply line 753 may be connected to the opening/closing valve 760 and the suck-back valve 770, respectively. The second supply line 752 and the third supply line 753 may supply gas to the opening/closing valve 760 and the suck-back valve 770.

The opening/closing valve 760 is installed in the liquid supply line 720. The opening/closing valve 760 opens/closes a flow of the treatment liquid. The opening/closing valve 760 may be a pressure proportional control valve. That is, opening/closing of the opening/closing valve 760 is determined through an electric signal.

The opening/closing valve 760 has a valve body 761. A piston member 762 that is vertically movable is installed in the valve body 761. The piston member 762 includes a piston, a shaft, and a disk. A shaft is coupled to a lower end of the piston. A disk is coupled to a lower end of the shaft. A spring 763 is installed above the piston member 762. The lower end of the spring 763 is in contact with the upper surface of the piston member 762, and the upper end of the spring 763 is in contact with the inner surface of the upper wall of the valve body 761.

The piston member 762 is moved up and down by a driver. In this case, air may be introduced or exhausted into a piston lower space 765 of the piston member 762 through an inlet 765a formed in the sidewall of the valve body 761. The flow path formed in the valve body 761 may be opened or closed while the disk is moved up and down according to the vertical movement of the piston member 762.

The suck-back valve 770 sucks a predetermined amount of the chemical liquid present at a front end of the nozzle 730 after the chemical liquid is discharged and retreats, thereby preventing a leakage of the chemical liquid. The suck-back valve 770 is disposed adjacent to a downstream of the cutoff valve 770. The suck-back valve 770 may be integrally provided with the cutoff valve 770. The suck-back valve 770 has a valve body 771. A piston member 771 that is vertically movable is installed in the valve body 771. The piston member 772 includes a piston, a shaft, and a diaphragm 774. An axis is vertically coupled to a lower surface of the piston, and the diaphragm 774 is coupled to a lower end of the shaft. A spring 773 is installed below the piston to surround the shaft. An upper end of the spring 773 is in contact with a lower surface of the piston, and a lower end of the spring 773 is in contact with a protrusion formed on an inner surface of a sidewall of the valve body 771. The diaphragm 774 coupled to a lower end of the shaft is located below the protrusion.

The piston member 762 is moved up and down by a driver, and the diaphragm 774 is moved up and down according to the vertical movement of the piston member 772. In this case, air may be introduced or exhausted into the piston lower space 765 of the piston member 762 through the inlet 765a formed in the sidewall of the valve body 761. The flow path formed in the valve body 761 may be opened or closed while the disk is moved up and down according to the vertical movement of the piston member 762. The flow path formed in the suck-back valve 770 communicates with the flow path formed in the opening/closing valve 760.

The pressure control device 780 is electrically connected to the opening/closing valve 760 and the suck-back valve 770. The pressure control device 780 may control the opening/closing valve 760 and the suck-back valve 770 by applying an electrical signal to the opening/closing valve 760 and the suck-back valve 770. The pressure control device 780 may control the pneumatic pressure applied to the opening/closing valve 760 and the suck-back valve 770.

A fan filter unit 383 for supplying downward airflow to the inner space is disposed on the upper wall of the housing 382. The fan filter unit 383 has a fan for introducing external gas into the inner space and a filter for filtering the external gas.

The outer cup 384 has a bottom wall 384a, a sidewall 384b, and an upper wall 384c. The inside of the outer cup 384 is provided as the aforementioned inner space. The inner space includes an upper treatment space and a lower exhaust space.

The bottom wall 384a is provided in a circular shape and has an opening in the center thereof. The sidewall 384b extends upward from the outer end of the bottom wall 384a. The sidewall 384b is provided in a ring shape and is provided perpendicular to the bottom wall 384a. For example, the sidewall 384b extends to the same height as the upper surface of the support plate 386a or extends to a height slightly lower than the upper surface of the support plate 386a. The upper wall 384c has a ring shape and an opening in the center thereof. The upper wall 384c is provided to be inclined upward from the upper end of the sidewall 384b toward the central axis of the outer cup 384.

The guide cup 385 is located inside the outer cup 384. The guide cup 385 has an inner wall 385a, an outer wall 385b, and an upper wall 385c. The inner wall 385a has a through hole penetrating in the vertical direction. The inner wall 385a is disposed to surround the driver 386c. The inner wall 385a minimizes the exposure of the driver 386c to the airflow 84 in the treatment space. The rotary shaft 386b or/and the driver 386c of the support unit 386 extend in the vertical direction through the through hole. The outer wall 385b is disposed to be spaced apart from the inner wall 385a and to surround the inner wall 385a. The outer wall 385b is positioned to be spaced apart from the sidewall 384b of the outer cup 384. The inner wall 385a is disposed to be spaced apart upward from the bottom wall 384a of the outer cup 384. The upper wall 385c connects the upper end of the outer wall 385b and the upper end of the inner wall 385a. The upper wall 385c has a ring shape and is disposed to surround the support plate 386a. According to an example, the upper wall 385c has a shape convex upward.

In the treatment space, a space below the support plate 386a may be provided as an exhaust space. According to an example, the exhaust space may be defined by the guide cup 385. A space surrounded by or below the outer wall 385b, the upper wall 385c, and the inner wall 385a of the guide cup 385 may be provided as an exhaust space.

The outer cup 384 may also be provided with a gas-liquid separator 389. The gas-liquid separator 389 may extend upward from the bottom wall 384a of the outer cup 384. The gas-liquid separating plate 389 may be provided in a ring shape. When viewed from above, the gas-liquid separator 389 may be positioned between the sidewall 384b of the outer cup 384 and the outer wall 385b of the guide cup 385. The upper end of the gas-liquid separator 389 may be positioned lower than the lower end of the outer wall 385b of the guide cup 385.

A discharge pipe 381a and an exhaust pipe 381b for discharging the treatment liquid are connected to the bottom wall 384a of the outer cup 384. The discharge pipe 381a may be connected to the outer cup 384 from the outside of the gas-liquid separator 389. The exhaust pipe 381b may be connected to the outer cup 384 from the inside of the gas-liquid separator 389.

The photographing device 800 may acquire an image of the nozzle 730. The photographing device 800 may acquire a first image which is an image of the nozzle 730 while the opening/closing valve 760 is closed. The photographing device 800 may acquire a second image which is an image of the nozzle 730 while the suck-back operation is performed. The photographing device 800 may transmit the first image and the second image to the controller 900.

The controller 900 may receive the first image and the second image from the photographing device 800. The controller 900 may control the liquid supply unit 700 and the photographing device 800. This will be described later.

Referring back to FIGS. 1 to 4, the interface module 500 connects the treating module 300 to an external exposure device 700. The interface module 500 includes an interface frame 501, a buffer unit 510, a cooling unit 520, a transfer mechanism 530, an interface robot 540, and an additional process chamber 560.

A fan filter unit that forms a descending airflow therein may be provided at an upper end of the interface frame 501. The buffer unit 510, the cooling unit 520, the transfer mechanism 530, the interface robot 540, and the additional process chamber 560 are disposed within the interface frame 501.

Structures and disposition of the buffer unit 510 and the cooling unit 520 may be provided to be the same as or similar to those of the buffer unit 310 and the cooling unit 320 provided in the treating module 300. The buffer unit 510 and the cooling unit 520 are disposed adjacent to an end portion of the transfer chamber 350. The substrate W transferred between the treating module 300, the cooling unit 520, the additional process chamber 560, and the exposure device 700 may remain temporarily in the buffer unit 510. The cooling unit 520 may be provided only at a height corresponding to the applying block 300a between the applying block 300a and the developing block 300b.

The transfer mechanism 530 may transfer the substrate W between the buffer units 510. In addition, the transfer mechanism 530 may transfer the substrate W between the buffer unit 510 and the cooling unit 520. The transfer mechanism 530 may be provided in the same or similar structure as or to the transfer mechanism 330 of the treating module 300. Another transfer mechanism 531 may be further provided in a region opposite to the region in which the transfer mechanism 530 is provided with respect to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface robot 540 has a hand 542 on which the substrate W is placed, and the hand 542 may be provided to move forward and backward, rotate based on an axis parallel to the third direction 16, and be movable along the third direction 16.

The additional process chamber 560 may perform a predetermined additional process before the substrate W on which the process has been completed in the applying block 300a is loaded into the exposure device 700. Optionally, the additional process chamber 560 may perform a predetermined additional process before the substrate W on which the process has been completed in the exposure device 700 is loaded into the developing block 300b. According to an example, the additional process may be an edge exposure process for exposing an edge region of the substrate W, an upper surface cleaning process for cleaning the upper surface of the substrate W, a lower surface cleaning process for cleaning the lower surface of the substrate W, or an inspection process of performing a predetermined inspection on the substrate W. A plurality of additional process chambers 560 may be provided, and they may be provided to be stacked on each other.

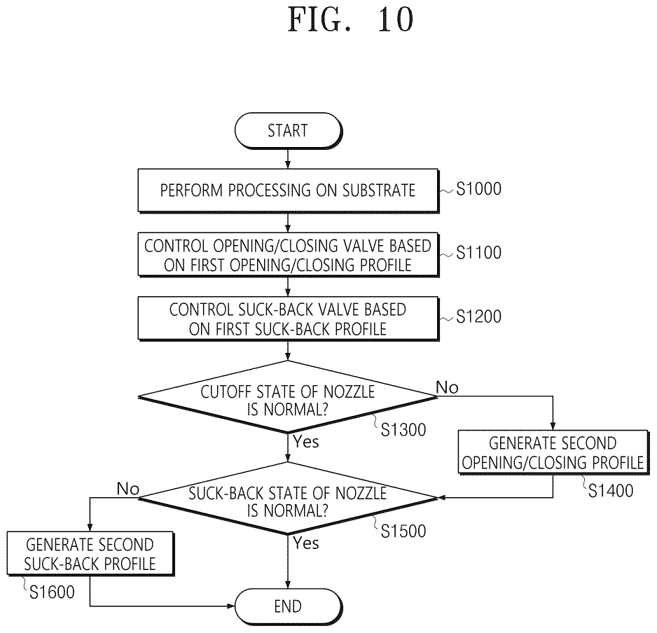

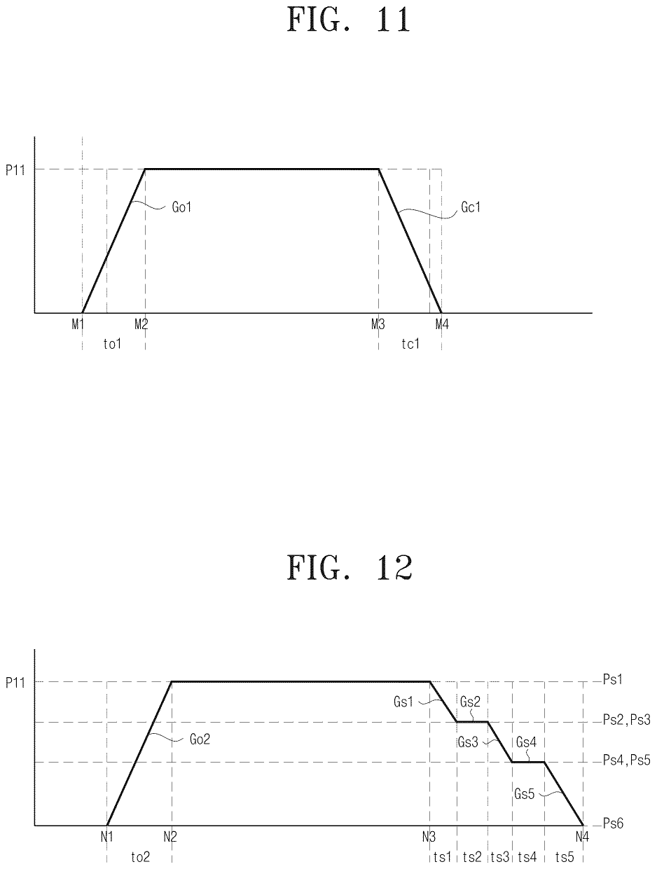

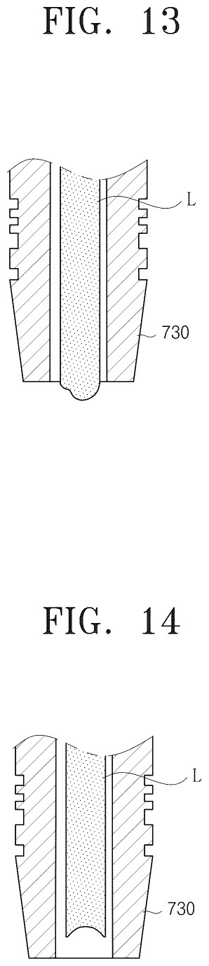

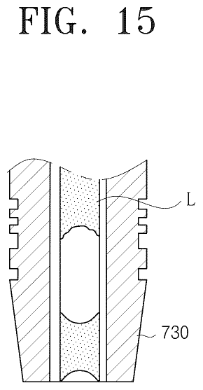

FIG. 10 is a flowchart illustrating a substrate processing method according to an exemplary embodiment of the present invention. FIG. 11 is a conceptual view for describing an opening/closing operation according to an exemplary embodiment of the present invention. FIG. 12 is a conceptual view for describing the suck-back operation according to an exemplary embodiment of the present invention. FIGS. 13 to 15 are diagrams for describing a cutoff state according to the exemplary embodiment of the present invention.

Referring to FIG. 10, the substrate processing apparatus may process a substrate (S1000). Referring to FIG. 11, the controller 900 may transmit a first open profile to the pressure control device 780. The first open profile may include information on a first open slope GO1, which is the slope of the pneumatic pressure applied to the opening/closing valve 760. Although only one first open slope GO1 is illustrated as an open slope, this is an example and the present invention is not limited thereto. The first open profile may be different depending on the type of treatment liquid.

The controller 900 may instruct the pressure control device 780 to open the opening/closing valve 760 based on the first open profile. The pressure control device 780 may open the opening/closing valve 760 during a first open time tO1 according to the first open slope GO1. The pneumatic pressure applied to the opening/closing valve 760 may become the first opening/closing pressure p11, and the flow path formed in the opening/closing valve 760 may be opened.

The controller 900 may transmit a second open profile to the pressure control device 780. The second open profile may include information on a second open slope GO2, which is a slope over time of the pneumatic pressure applied to the suck-back valve 760.

The controller 900 may instruct the pressure control device 780 to open the suck-back valve 770 based on the second open profile. The pressure control device 780 may open the suck-back valve 770 during a second open time tO2 according to the second open slope GO2. The start time N1 and the end time N2 of the second open time t02 may be different from the start time M1 and the end time M2 of the first open time t01.

The pneumatic pressure applied to the suck-back valve 770 may be the first suck-back pressure p21 at 0, and the flow path formed in the suck-back valve 770 may be opened. In this case, a treatment liquid may be supplied to the substrate W through the nozzle 730, and accordingly, treatment on the substrate w may be performed. In this case, the pneumatic pressure applied to the opening/closing valve 760 and the suck-back valve 770 may be constantly maintained at the first opening/closing pressure p11 and the first suck-back pressure PS1.

The substrate processing apparatus may perform control on the opening/closing valve based on the first opening/closing profile (S1100). When the processing of the substrate w is performed in S1000, the controller 900 may transmit the first opening/closing profile to the pressure control device 780. Referring to FIG. 11, the first opening/closing profile may include information on a closing slope GC1 which is a slope of the pneumatic pressure applied to the opening/closing valve 760 over time. Although only one closing slope GC1 is illustrated as a closing slope, this is an example and the present invention is not limited thereto. The first opening/closing profile may be different depending on a type of a treatment liquid.

The controller 900 may instruct the pressure control device 780 to close the opening/closing valve 760 based on the first opening/closing profile. The pressure control device 780 may close the opening/closing valve 760 during a first closing time tC1 depending on a closing slope. The pneumatic pressure applied to the opening/closing valve 760 may be 0 at the first opening/closing pressure p11, and the flow path formed at the opening/closing valve 760 may be closed. An amount of the treatment liquid supplied to the substrate W through the nozzle 730 may become 0.

Furthermore, the controller 900 may instruct the photographing device 800 to acquire the first image which is an image of the nozzle 730 while the opening/closing valve 760 is closed. The photographing device 800 may acquire the first image and transmit the first image to the controller 900. The controller 900 may receive the first image from the photographing device 800.

The substrate processing apparatus may perform control on the suck-back valve based on the first suck-back profile (S1200). The controller 900 may transmit the first suck-back profile to the pressure control device 780. Referring to FIG. 12, the first suck-back profile may include information on a first suck-back slope GS1 to a fifth suck-back slope GS5, which are slopes over time of the pneumatic pressure applied to the suck-back valve. Although five suck-back slopes GS1 to GS5 are illustrated in the drawings, these are examples and the present invention is not limited thereto. The first suck-back profile may differ depending on a type of a treatment liquid.

The controller 900 may instruct the pressure control device 780 to control the suck-back valve 770 to perform the suck-back operation based on the first suck-back profile.

The pressure control device 780 may control the suck-back valve 770 to perform the suck-back operation based on the first suck-back profile.

The pressure control device 780 may control the pneumatic pressure applied to the suck-back valve 770 based on the first suck-back slope GS1 and adjust the pressure of the suck-back valve 770 from the first suck-back pressure pS1 to the second suck-back pressure pS2 for the first suck-back time tS1. The start time N2 of the first suck-back time tS21 may differ from the start time M2 of the first closing time tC1. In this case, the suck-back operation may start in the middle of closing the opening/closing valve 770. Unlike this, the start time N2 of the first suck-back time tS21 and the start time M2 of the first closing time tC1 may be the same, and the suck-back operation may start at the moment when the opening/closing valve 760 starts to close. Also, the start time N2 of the first suck-back time tS21 and the end time M3 of the first closing time tC1 may be the same. In this case, the suck-back operation may start after the opening/closing valve 770 is closed.

The first suck-back slope GS1 may not be 0. The pressure of the suck-back valve 770 may be a pressure of the upper space 775 of the piston member 772. Also, the first suck-back pressure pS1 may be greater than the second suck-back pressure pS2. In this case, the diaphragm 774 may rise, and the suck-back operation may be performed.

The pressure control device 780 may control the pneumatic pressure applied to the suck-back valve 770 based on the second suck-back slope GS2 and adjust the pressure of the suck-back valve 770 from the second suck-back pressure pS2 to the third suck-back pressure pS3 for the second suck-back time tS2. The second suck-back slope GS2 may be 0, and the second suck-back pressure pS2 may be equal to the third suck-back pressure pS3. In this case, the height of the diaphragm 774 may be maintained and the suck-back operation may be performed.

The pressure control device 780 may control the pneumatic pressure applied to the suck-back valve 770 based on the third suck-back slope G23 and adjust the pressure of the suck-back valve 770 from the third suck-back pressure pS3 to the fourth suck-back pressure pS4 for the third suck-back time tS3. The third suck-back inclination G23 may not be zero. Also, the third suck-back pressure pS3 may be greater than the fourth suck-back pressure pS4. In this case, the diaphragm 774 may rise, and the suck-back operation may be performed.

The pressure control device 780 may control the pneumatic pressure applied to the suck-back valve 770 based on the fourth suck-back slope GS4 and adjust the pressure of the suck-back valve 770 from the fourth suck-back pressure pS4 to the fifth suck-back pressure pS5 for the fourth suck-back time tS4. The fourth suck-back slope G22 may be 0, and the fourth suck-back pressure pS4 may be equal to the fifth suck-back pressure pS5. In this case, the height of the diaphragm 774 may be maintained and the suck-back operation may be performed.

The pressure control device 780 may control the pneumatic pressure applied to the suck-back valve 770 based on the fifth suck-back slope GS5 to adjust the pressure of the suck-back valve 770 from the fifth suck-back pressure pS5 to the sixth suck-back pressure pS6 for the fifth suck-back time tS5. The end time point N4 of the fifth suck-back time tS5 may be different from the end time point M4 of the first closure time tC1. The fifth suck-back GS5 may not be zero. Also, the fifth suck-back pressure pS5 may be greater than the sixth suck-back pressure pS6. In this case, the diaphragm 774 may be raised, and the suck-back operation may be performed. For example, the sixth suck-back pressure pS6 may be zero.

Furthermore, the controller 900 may instruct the photographing device 800 to acquire the second image, which is an image of the nozzle 730, while the suck-back operation is performed. The photographing device 800 may acquire the second image and transmit the second image to the controller 900. The controller 900 may receive the second image from the photographing device 800.

The substrate processing apparatus may determine whether the cutoff state of the nozzle is normal (S1300). The controller 900 may determine whether the cutoff state of the nozzle 730 is normal based on the first image received in step S1100.

Referring to FIG. 13, in a case where the closing slope GC1 is smaller than a preset value, the closing valve 760 closes more slowly than the normal speed, thereby causing liquid sagging at the nozzle 730, the controller 900 may determine that the cutoff state of the nozzle 730 is abnormal.

Referring to FIG. 14, in a case where the closing slope GC1 is smaller than a preset value, the closing valve 760 closes more slowly than the normal speed, thereby causing a cutoff delay at the nozzle 730, the controller 900 may determine that the cutoff state of the nozzle 730 is abnormal.

Referring to FIG. 15, in a case where the closing slope GC1 is greater than a preset value, the closing valve 760 closes faster than the normal speed, thereby causing liquid separation at the nozzle 730, the controller 900 may determine that the cutoff state of the nozzle 730 is abnormal.

In addition, although not illustrated in the drawing, in a case where the closing slope GC1 is greater than a preset value, the closing valve 760 closes faster than the normal speed, thereby causing liquid splashing, the controller 900 may determine that the cutoff state of the nozzle is abnormal.

When it is determined that the cutoff state of the nozzle is abnormal (NO in S1300), the substrate processing apparatus may generate a second opening/closing profile (S1400). The controller 900 may generate a second opening/closing profile by correcting the closing slope of the first opening/closing profile.

For example, when the liquid sagging or the cutoff delay occurs at the nozzle 730 as illustrated in FIGS. 13 to 14, the controller 900 may correct the closing slope by increasing the magnitude of the closing slope to generate a second opening/closing profile. The controller 900 may transmit the second opening/closing profile to the pressure control device 780, and instruct the pressure control device 780 to control the opening/closing valve 760 based on the second opening/closing profile.

When the liquid separation phenomenon occurs at the nozzle 730 or the liquid splashing phenomenon occurs as illustrated in FIG. 15, the controller 900 may correct the closing slope in a manner of reducing a magnitude of the closing slope to generate a second opening/closing profile. The controller 900 may transmit the second opening/closing profile to the pressure control device 780.

The substrate processing apparatus may determine whether the suck-back state of the nozzle is normal (S1500). The controller 900 may determine whether the cutoff state of the nozzle 730 is normal based on the second image received in step S1200.

The controller 900 may determine whether the suck-back state of the nozzle 730 is normal based on the second image received in step S1200. When the height of the treatment liquid remaining in the nozzle 730 is out of a preset range, the controller 900 may determine that the suck-back state of the nozzle 730 is abnormal.

When it is determined that the suck-back state of the nozzle is abnormal (NO in S1500), the substrate processing apparatus may generate a second suck-back profile (S1600). The controller 900 may correct at least one of a plurality of slopes of the first suck-back profile to generate the second opening/closing profile. The controller 900 may transmit the second suck-back profile to the pressure control device 780 and instruct the pressure control device 780 to control the suck-back valve 770 based on the second suck-back profile.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

1. A method of processing a substrate, the method comprising:
processing a substrate by supplying a treatment liquid to the substrate through a liquid supply line in which an opening/closing valve and a suck-back valve are installed;
closing the opening/closing valve based on a first opening/closing profile; and
performing a suck-back operation based on a first suck-back profile,
wherein the first opening/closing profile includes information on a closing slope, which is a slope of a pneumatic pressure applied to the opening/closing valve over time,
the first suck-back profile includes information on a suck-back slope, which is a slope of a pneumatic pressure applied to the suck-back valve over time, and
the first suck-back profile includes a plurality of different suck-back slopes.

2. The method of claim 1, wherein the first suck-back profile includes:
a first suck-back slope, which is a slope for a first time; and
a second suck-back slope, which is a slope for a second time after the first time,
the first suck-back slope is a non-zero slope, and
the second suck-back slope is zero.

3. The method of claim 2, wherein the performing of the suck-back operation based on the first suck-back profile includes:
adjusting a pressure of the suck-back valve from a first suck-back pressure to a second suck-back pressure by controlling the pneumatic pressure applied to the suck-back valve based on the first suck-back slope; and
adjusting a pressure of the suck-back valve from the second suck-back pressure to a third suck-back pressure by controlling the pneumatic pressure applied to the suck-back valve based on the second suck-back slope.

4. The method of claim 3, wherein the performing of the suck-back operation based on the first suck-back profile further includes acquiring a second image, which is an image of a nozzle, while the suck-back operation is performed, and
the method further comprises:
determining whether a suck-back state of the nozzle is normal based on the second image; and
when it is determined that the suck-back state of the nozzle is abnormal, correcting at least one of the plurality of suck-back slopes to generate a second suck-back profile.

5. The method of claim 4, wherein the determining of whether the suck-back state of the nozzle is normal based on the second image is determining that the suck-back state of the nozzle is abnormal when a height of the treatment liquid remaining in the nozzle is out of a preset range.

6. The method of claim 1, wherein the closing of the opening/closing valve based on the first opening/closing profile further includes acquiring a first image, which is an image of a nozzle, while the opening/closing valve is closed, and
the method further comprises:
determining whether a cutoff state of the nozzle is normal based on the first image; and
when it is determined that the cutoff state of the nozzle is abnormal, correcting the closing slope to generate a second opening/closing profile.

7. The method of claim 6, wherein the determining of whether the cutoff state of the nozzle is normal based on the first image is determining that the cutoff state of the nozzle is abnormal based on the first image when a liquid splashing phenomenon, layer separation phenomenon, cutoff delay phenomenon, or liquid sagging phenomenon occurs at the nozzle.

8. The method of claim 7, wherein the generating of the second opening/closing profile is generating the second opening/closing profile by performing the correction on the closing slope in a manner of reducing a magnitude of the closing slope when the liquid splashing phenomenon or the layer separation phenomenon occurs at the nozzle.

9. The method of claim 7, wherein the generating of the second opening/closing profile is generating the second opening/closing profile by performing the correction on the closing slope in a manner of increasing a magnitude of the closing slope when the cutoff delay phenomenon or the liquid sagging phenomenon occurs at the nozzle.

10. The method of claim 1, wherein the first opening/closing profile and the first suck-back profile are different depending on the type of the treatment liquid.

11. (canceled)

12. (canceled)

13. (canceled)

14. (canceled)

15. (canceled)

16. (canceled)

17. A method of processing a substrate, the method comprising:
processing a substrate by supplying a treatment liquid to the substrate through a liquid supply line in which an opening/closing valve and a suck-back valve are installed;
closing the opening/closing valve based on a first opening/closing profile; and
performing a suck-back operation based on a first suck-back profile,
the first opening/closing profile includes information on a closing slope, which is a slope of a pneumatic pressure applied to the opening/closing valve over time,
the first suck-back profile includes information on a suck-back slope, which is a slope of the pneumatic pressure applied to the suck-back valve over time, and
the suck-back slope is plural,
the performing of the suck-back operation based on the first suck-back profile includes:
adjusting a pressure of the suck-back valve from a first suck-back pressure to a second suck-back pressure by controlling the pneumatic pressure applied to the suck-back valve based on a first suck-back slope among the plurality of suck-back slopes;
adjusting a pressure of the suck-back valve from the second suck-back pressure to a third suck-back pressure by controlling the pneumatic pressure applied to the suck-back valve based on a second suck-back slope among the plurality of suck-back slopes; and
the second suck-back pressure and the third suck-back pressure are the same pressure.

18. The method of claim 17, wherein the first suck-back profile includes:
a first suck-back slope, which is a slope for a first time; and
a second suck-back slope, which is a slope for a second time after the first time,
the first suck-back slope is a non-zero slope, and
the second suck-back slope is zero.

19. The method of claim 18, wherein the closing of the opening/closing valve based on the first opening/closing profile further includes acquiring a first image, which is an image of a nozzle, while the opening/closing valve is closed, and
the method further comprises:
determining whether a cutoff state of the nozzle is normal based on the first image; and
when it is determined that the cutoff state of the nozzle is abnormal, correcting the closing slope to generate a second opening/closing profile.

20. The method of claim 18, wherein the performing of the suck-back operation based on the first suck-back profile further includes acquiring a second image, which is an image of a nozzle, while the suck-back operation is performed, and
the method further comprises:
determining whether a suck-back state of the nozzle is normal based on the second image; and
when it is determined that the suck-back state of the nozzle is abnormal, correcting at least one of the plurality of suck-back slopes to generate a second suck-back profile.
